(19) United States
(12) Patent Application Publication
(10) Pub. No.: US 2016/0155994 A1
(43) Pub. Date: Jun. 2, 2016

(54) ORGANIC LIGHT-EMITTING DIODE AND METHOD OF FABRICATING THE SAME

(71) Applicant: ELECTRONICS AND TELECOMMUNICATIONS RESEARCH INSTITUTE, Daejeon (KR)

(72) Inventors: Doo-Hee CHO, Daejeon (KR); JEONG IK LEE, Daejeon (KR); Jin Wook SHIN, Daejeon (KR); Jin Woo HUH, Daejeon (KR); Nam Sung CHO, Daejeon (KR); Jonghee LEE, Daejeon (KR); Seung Koo PARK, Daejeon (KR); Jaehyun MOON, Daejeon (KR)

(73) Assignee: ELECTRONICS AND TELECOMMUNICATIONS RESEARCH INSTITUTE, Daejeon (KR)

(21) Appl. No.: 15/017,758

(22) Filed: Feb. 8, 2016

Related U.S. Application Data
(62) Division of application No. 14/243,284, filed on Apr. 2, 2014.

(30) Foreign Application Priority Data
Aug. 9, 2013 (KR) 10-2013-0094913

(51) Int. Cl. H01L 51/56; H01L 51/52

(52) U.S. Cl. CPC H01L 51/56; H01L 51/5268; H01L 51/5253; H01L 2251/301; H01L 2251/303; H01L 2251/558; H01L 2251/5369

(57) ABSTRACT

Provided is a method of manufacturing an organic light-emitting diode including forming an anode on a substrate, forming an organic light-emitting layer on the anode, forming a cathode on the organic light-emitting layer, and forming a light scattering film on the cathode. The light scattering film is a polycrystalline dielectric material composed of anisotropic crystals, and a surface roughness Ra of a top surface of the light scattering film is greater than or equal to about 50 nm by an anisotropic crystal growth of particles of the dielectric material.

### CROSS-REFERENCE TO RELATED APPLICATIONS

This is a division of application Ser. No. 14/243,284, filed Apr. 2, 2014. Further, this U.S. non-provisional patent application claims priority under 35 U.S.C. §119 of Korean Patent Application No. 10-2013-0094913, filed on Aug. 9, 2013. The entire contents of these prior applications are hereby incorporated by reference.

### BACKGROUND OF THE INVENTION

The present disclosure herein relates to an organic light-emitting diode and a method of fabricating the same, and more particularly, to an organic light-emitting diode including a light-scattering film and a method of fabricating the same.

Recently, there has been an increasing demand on weight lightening, downsizing and moderate prices for electronic products and a lighting installation including a cellular phone, a laptop computer, etc. To satisfy the above demands, an organic light-emitting device receives attention as a display apparatus and a light-emitting apparatus installed in the electronic products and the lighting installation. Particularly, the organic light-emitting device has advantages of a low voltage driving, a light weight and low cost, and the utilization thereof in the electronic products and the lighting installation is high.

Recently, researches on increasing the light-emitting efficiency of an organic light-emitting device are performed. Particularly, various researches on attaining high light-emitting efficiency at a low voltage by extracting out escaping light from the inner portion of the organic light-emitting device are performed.

### SUMMARY OF THE INVENTION

The present disclosure provides an organic light-emitting diode having improved light-extracting efficiency by restraining the absorption of surface plasmons by a cathode.

The present disclosure also provides a method of manufacturing an organic light-emitting diode having improved light-extracting efficiency by restraining the absorption of surface plasmons by a cathode.

The tasks to be solved by the present inventive concept is not limited to the above-described tasks, however other tasks not mentioned will be precisely understood from the following description by a person skilled in the art.

Embodiments of the inventive concept provide methods of manufacturing an organic light-emitting diode including forming an anode on a substrate, forming an organic light-emitting layer on the anode, forming a cathode on the organic light-emitting layer, and forming a light scattering film on the cathode. The light scattering film is a polycrystalline dielectric material composed of anisotropic crystals, a smooth surface is not formed but a rough surface is voluntarily formed during performing a deposition process, and a surface roughness Ra of a top surface of the light scattering film is greater than or equal to about 50 nm by an anisotropic crystal growth of particles of the dielectric material.

In some embodiments, the light scattering film may be formed by a thermal evaporation method, a chemical vapor deposition method, or a facing target sputtering method while maintaining the temperature of the substrate at 100° C. or less.

In other embodiments, the dielectric material may include BaCl₂, BaBr₂, BaS, CsCl, CsBr, CsBr₂, PbO, LiCl, LiBr, SeCl₄, MgBr₂, AgCl, AgBr, TeO₂, SnF₄, SnCl₄, SnBr₄, ZnCl₂, TiO₂, WO₃, ZnO, indium tin oxide (ITO), SnO₂, In₂O₃, ZrO₂, AgCl, ZnS or TeO₂.

In still other embodiments, the light scattering film including BaCl₂, BaBr₂, BaS, CsCl, CsBr, CsBr₂, PbO, LiCl, LiBr, SeCl₄, MgBr₂, AgCl, AgBr, TeO₂, SnF₄, SnCl₄, SnBr₄ or ZnCl₂ may be formed by a thermal evaporation method.

In even other embodiments, the light scattering film including TiO₂, WO₃, ZnO, ITO, SnO₂, In₂O₃ or ZrO₂ may be formed by a chemical vapor deposition method.

In yet other embodiments, the light scattering film including TiO₂, WO₃, ZnO, ITO, SnO₂, In₂O₃, ZrO₂, AgCl, ZnS or TeO₂ may be formed by a facing target sputtering method.

In further embodiments, the light scattering film may have a thickness of from about 200 nm to about 2,000 nm.

In still further embodiments, the method may further include forming a passivation layer on the cathode prior to forming the light scattering film.

In even further embodiments, the passivation layer may include at least one among an organic material, a metal oxide and a metal nitride.

In yet further embodiments, the method may further include forming metal nanoparticles in the light scattering film.

In much further embodiments, the metal nanoparticles may be formed by a co-deposition method, by performing a heat treatment with the light scattering film, exposing the light scattering film to ultraviolet light, or forming a gas atmosphere into a reducing atmosphere during forming the light scattering film.

In still much further embodiments, the metal nanoparticles may include Ba, Cs, Ca, Pb, Li, Se, Mg, Ag, Te, Sn, Zn, Ti, W, In, Zr or Te.

In other embodiments of the inventive concept, organic light-emitting diodes include an anode on a substrate, an organic light-emitting layer disposed on the anode, a cathode disposed on the organic light-emitting layer, and a light scattering film on the cathode. The light scattering film is a polycrystalline dielectric material composed of anisotropic crystals, and a surface roughness Ra of a top surface of the light scattering film is greater than or equal to about 50 nm by an anisotropic crystal growth of particles of the dielectric material.

In some embodiments, the dielectric material may include BaCl₂, BaBr₂, BaS, CsCl, CsBr, CsBr₂, PbO, LiCl, LiBr, SeCl₄, MgBr₂, AgCl, AgBr, TeO₂, SbF₄, SbCl₄, SnBr₄, ZnCl₂, TiO₂, WO₃, ZnO, ITO, SnO₂, In₂O₃, ZrO₂, AgCl, ZnS or TeO₂.

In other embodiments, the organic light-emitting layer may include a hole injection layer, a hole transport layer, an emission layer, an electron transport layer and an electron injection layer sequentially stacked on the anode. A gap between a top surface of the emission layer and a top surface of the cathode may be from about 30 nm to about 160 nm.

In still other embodiments, the organic light-emitting diode may further include metal nanoparticles in the light scattering film.

In even other embodiments, the metal nanoparticles may include Ba, Cs, Ca, Pb, Li, Se, Mg, Ag, Te, Sn, Zn, Ti, W, In, Zr or Te.

In yet other embodiments, a passivation layer may be further interposed between the cathode and the light scattering film.

In further embodiments, the light scattering film may have a thickness of from about 200 nm to about 2,000 nm.

In still further embodiments, the light scattering film may have a refractive index of from about 1.65 to about 2.3.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view of an organic light-emitting diode according to a First Embodiment of the inventive concept;

FIG. 2 is a flowchart illustrating a method of manufacturing an organic light-emitting diode according to a First Embodiment of the inventive concept;

FIG. 3 is a cross-sectional view of an organic light-emitting diode according to a Second Embodiment of the inventive concept;

FIG. 4 is a cross-sectional view of an organic light-emitting diode according to a Third Embodiment of the inventive concept; and

FIG. 5 is a cross-sectional view of an organic light-emitting diode according to a Fourth Embodiment of the inventive concept.

### DETAILED DESCRIPTION OF PREFERRED EMBODIMENTS

The advantages and the features of the inventive concept, and methods for attaining them will be described in example embodiments below with reference to the accompanying drawings. The inventive concept may, however, be embodied in different forms and should not be construed as limited to the embodiments set forth herein. Rather, these embodiments are provided so that this description will be thorough and complete, and will fully convey the scope of the present inventive concept to those skilled in the art.

The terminology used herein is for the purpose of describing particular example embodiments only and is not intended to limit the present inventive concept. As used herein, the singular forms are intended to include the plural forms as well, unless the context clearly indicates otherwise. It will be further understood that the terms “comprises” and/or “comprising,” when used in this specification, specify the presence of stated features, steps, operations, and/or devices, but do not preclude the presence or addition of one or more other features, steps, operations, and/or devices thereof.

Example embodiments are described herein with reference to cross-sectional views and/or plan views that are schematic illustrations of idealized example embodiments. In the drawings, the sizes and relative sizes of layers and regions may be exaggerated for effective explanation of technical contents. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, a region illustrated as a rectangle will, typically, have rounded or curved features. Thus, the regions illustrated in the figures are schematic in nature and their shapes are not intended to illustrate the actual shape of a region of a device and are not intended to limit the scope of the present inventive concept.

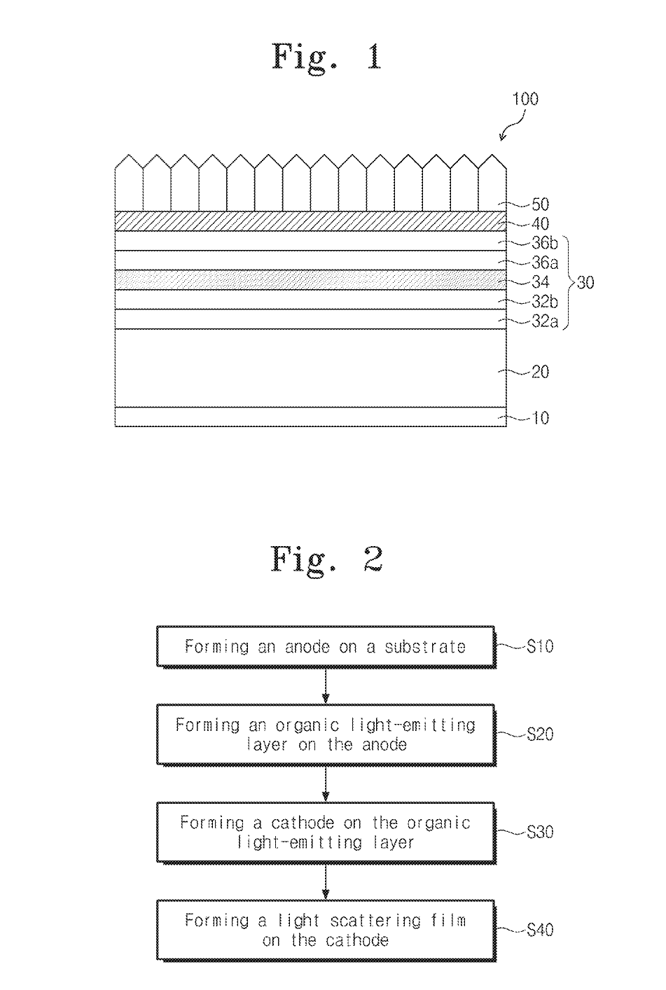

FIG. 1 is a cross-sectional view of an organic light-emitting diode according to a First Embodiment of the inventive concept. FIG. 2 is a flowchart illustrating a method of manufacturing the organic light-emitting diode according to the First Embodiment of the inventive concept.

Referring to FIGS. 1 and 2, in an organic light-emitting diode 100, an anode 20 is formed on a substrate 10 (Step S10). The substrate 10 may include a glass substrate, a quartz substrate, a plastic substrate, or a metal substrate. The substrate 10 may be used as a reflection substrate.

The anode 20 may include a transparent conductive material. The anode 20 may include, for example, one of transparent conductive oxides (TCO) and a conductive carbon material. More particularly, the anode 20 may include indium tin oxide (ITO) or indium zinc oxide (IZO). In another embodiment, the anode 20 may include a conductive organic thin film. The anode 20 may include at least one conductive organic material among, for example, copper iodide, polyaniline, poly(3-methylthiophene) and polypyrrole. In another embodiment, the anode 20 may include a graphene thin film.

An organic light-emitting layer 30 is formed on the anode 20 (Step S20). The organic light-emitting layer 30 may include a hole injection layer 32a, a hole transport layer 32b, an emission layer 34, an electron transport layer 36a and an electron injection layer 36b sequentially stacked on the anode 20.

The hole injection layer 32a may include at least one selected from the group consisting of copper phthalocyanine (CuPc), 4,4′,4″-tris[N-(1-naphthyl)-N-phenylamino]-triphenylamine (2-TNANA), 4,4′,4″-tris(N-carbazolyl-9-yl)triphenylamine (TCTA), poly(3,4-ethylenedioxythiophene) (PEDOT), polyaniline (PANI) and polystyrene sulfonate (PSS).

The highest occupied molecular orbital (HOMO) corresponds to the highest energy level of a valence band, and the lowest unoccupied molecular orbital (LUMO) corresponds the lowest energy level of a conduction band.

By decreasing the difference between the level of the work function of the anode 20 and the HOMO level of the hole transport layer 32b, the hole injection layer 32a may easily perform the injection of holes from the anode 20 to the hole transport layer 32b. Therefore, the driving current or the driving voltage of the organic light-emitting diode 100 may be decreased by the hole injection layer 32a.

The hole transport layer 32b may include a polymer derivative including poly(9-vinylcarbazole), a polymer derivative including 4,4′-dicarbazolyl-1,1′-diamine, a polymer derivative including 4,4′-bis[N-(1-naphthyl-1-)-N-phenylamino]-biphenyl (NPB), a low molecular weight derivative including triarylamine, a low molecular weight derivative including pyrazoline, or an organic molecule including a hole transporting moiety.

The hole transport layer 32b may provide the holes moved through the hole injection layer 32a to the emission layer 34. The HOMO level of the hole transport layer 32b may be higher than the HOMO level of the emission layer 34.

The emission layer 34 may include a fluorescent material or a phosphorescent material. The emission layer 34 may include, for example, DPVBi, IDE 120, IDE 105, Alq3, CBP, DCJTB, BSN, DPP, DSB, PESB, a PPV derivative, a PFO derivative, C545t, Ir(ppy)₃, and PtOEP. The emission layer 34 may be a single layer or a multi layer.

The electron transport layer 36a may include 2,2′,2′-(1,3,5-phenylene)-tris[1-phenyl-1H-benzimidazole (TPBI), poly(phenylquinoxaline), 1,3,5-tris[6,7-dimethyl-3-phenyl)quinoxaline-2-yl]benzene (Me-TPQ), polyquinoline, tris(8-hydroxyquinoline)aluminum (Alq3), {6-N,N-diethylamino-1-methyl-3-phenyl-1H-pyrazolo[3,4-b]quinoline} (PAQ-Net2), or at least one organic molecule including an electron transporting moiety.

The electron injection layer 36b may include a material having high electron mobility. The electron injection layer 36b may include lithium (Li), magnesium (Mg), aluminum (Al), calcium (Ca), silver (Ag) or cesium (Cs). The electron injection layer 36b may include, for example, lithium fluoride (LiF) or cesium fluoride (CsF). The electron injection layer 36b has the function of stably supplying electrons to the emission layer 34.

The electron transport layer 36a and/or the electron injection layer 36b may have the thickness of from about 20 nm to about 100 nm.

A cathode 40 is formed on the organic light-emitting layer 30 (Step S30). The cathode 40 may include a conductive material having a lower work function than the anode 20. In an embodiment, the cathode 40 may include a conductive material that is semi-transparent or that has high reflectance. The cathode 40 may include, for example, aluminum (Al), gold (Au), silver (Ag), iridium (Ir), molybdenum (Mo), palladium (Pd) or platinum (Pt). The cathode 40 may have the thickness of from about 10 nm to about 60 nm. In an embodiment, the distance from the top surface of the emission layer 40 and the top surface of the cathode 40 may be from about 30 nm to about 160 nm.

A light scattering film 50 is formed on the cathode 40 (Step S40).

The light scattering film 50 may be formed by depositing a dielectric material. The light scattering film 50 may be formed by, for example, a thermal evaporation method, a chemical vapor deposition method, or a facing target sputtering method on the cathode 40.

The thermal evaporation method is a method of forming the light scattering film 50 by melting and vaporizing the dielectric material by using an electron beam or an electrical filament under a high-degree vacuum (about 5×10⁻⁵ to about 1×10⁻⁷ torr), and depositing the vaporized dielectric material on the cathode 40. The vaporizing temperature of the dielectric material may be maintained to about 1,200° C. or less. The dielectric material that may form the light scattering film 50 by means of the thermal evaporation method may include BaCl₂, BaBr₂, BaS, CsCl, CsBr, CsBr, PbO, LiCl, LiBr, SeCl₄, MgBr₂, AgCl, AgBr, TeO₂, SnF₄, SnCl₄, SnBr₄ or ZnCl₂.

The facing target sputtering method is a method of forming the light scattering film 50 on the cathode 50 by disposing two facing targets and the cathode 50 at a vertical position between the targets. According to the facing target sputtering method, the damage of the organic light-emitting layer 30 adjacent to the cathode 40 may be restrained when compared to a general sputtering method by which a thin film is deposited by facing a depositing substrate and a target. The dielectric material that may form the light scattering film 50 by means of the facing target sputtering method may include TiO₂, WO₃, ZnO, ITO, SnO₂, In₂O₃, ZrO₂, AgCl, ZnS or TeO₂.

The chemical vapor deposition method is a method of forming the light scattering film 50 by a low temperature process. The dielectric material that may form the light scattering film 50 by means of the chemical vapor deposition method may include TiO₂, WO₃, ZnO, ITO, SnO₂, In₂O₃ or ZrO₂.

According to an embodiment, the light scattering film 50 may be formed while maintaining the temperature of the substrate to about 100° C. or less by means of the above deposition methods. According to the above deposition methods, the light scattering film 50 may be formed at a relatively lower deposition temperature than other deposition methods and under vacuum. Thus, the damage of the emission layer 34 while forming the light scattering film 50 on the cathode 40 may be decreased.

The light scattering film 50 may be transparent and have a high refractive index. Particularly, the light scattering film 50 may have the refractive index of about 1.65 to about 2.3. In addition, the light scattering film 50 may be a polycrystalline dielectric material film composed of anisotropic crystals. The polycrystalline material is a solid that is composed of many crystallites of random orientation. The dielectric material composing the light scattering film 50 may have crystalline particles, and the crystalline particles may grow in different directions according to the crystalline direction formed at the initial time of the deposition. The growth rate may be different depending on the crystalline direction. In addition, since the crystalline growth rate of the anisotropic crystals may be different according to crystalline axes, a polycrystalline film composed of the anisotropic crystals may form a rough surface voluntarily. Thus, the light scattering film 50 may not have a smooth surface but may have a rough surface. The top surface of the light scattering film 50 may have a surface roughness (Ra) of about 50 nm or above. The light scattering film 50 may have the thickness of about 200 nm to about 2,000 nm.

The light emitted from the emission layer 30 may be lost through the absorption by the cathode due to a surface plasmon effect by the cathode 40. The loss of the light due to the surface plasmon effect may be largely dependent on the thickness of the electron transport layer 22a and/or the electron injection layer 22b. The thickness of the electron transport layer 22a and/or the electron injection layer 22b may be increased to restrain the absorption of the light by the cathode 40. However, when the thickness of the electron transport layer 22a and/or the electron injection layer 22b is increased, the electron injection efficiency of the electron transport layer 22a and/or the electron injection layer 22b may be decreased, and light-emitting efficiency may be decreased.

In an embodiment, the light scattering film 50 may be formed on the cathode 40 for the outcoupling of surface plasmon polaritons from the cathode 40 and releasing thereof outward. Thus, the absorption of the light by the cathode 40 may be prevented by the surface plasmon. In addition, the rough surface of the light scattering film 50 may not form guided modes in the light scattering film 50 but may be scattered in all directions. Therefore, the light may be released outward without loss, and light extracting efficiency may be improved.

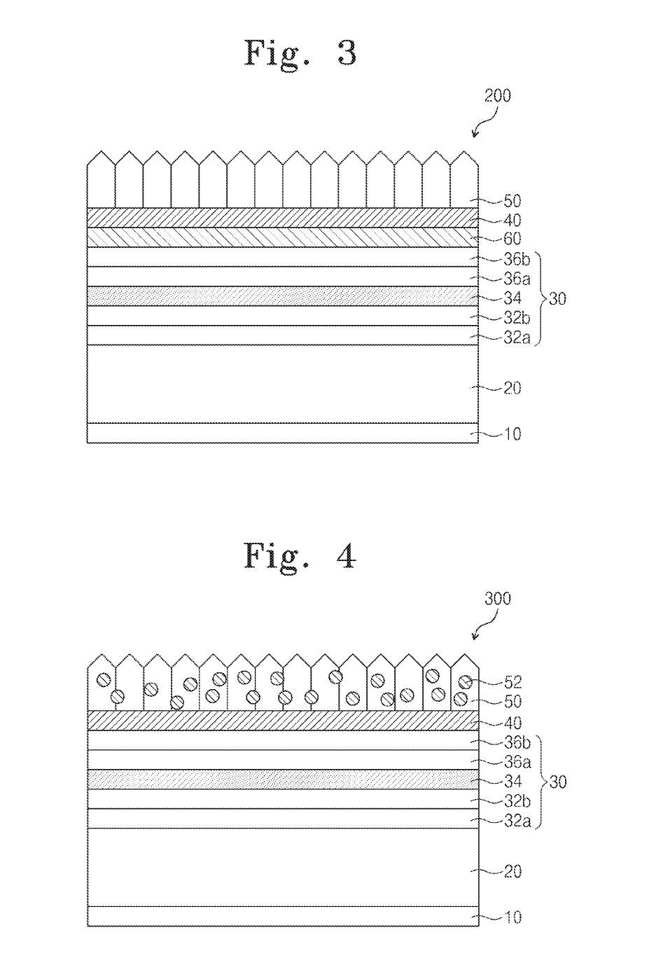

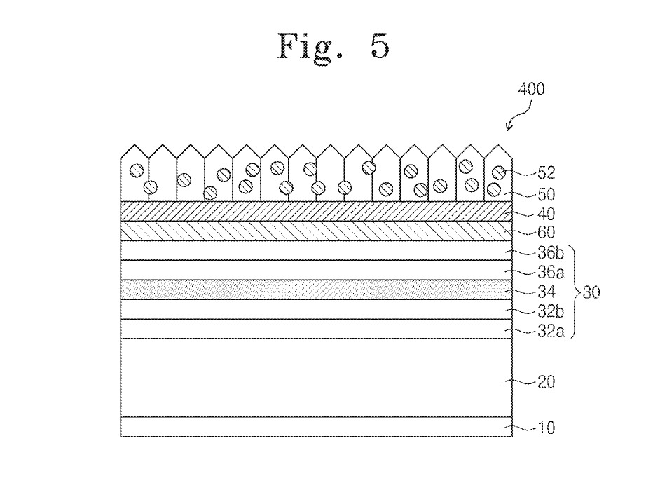

FIG. 3 is a cross-sectional view of an organic light-emitting diode according to a Second Embodiment of the inventive concept. FIG. 4 is a cross-sectional view of an organic light-emitting diode according to a Third Embodiment of the inventive concept. FIG. 5 is a cross-sectional view of an organic light-emitting diode according to a Fourth Embodiment of the inventive concept. For brevity of explanation, the same reference numerals are used for substantially the same constituting elements in the embodiment, and explanation on corresponding constituting elements will be omitted in another embodiment illustrated in FIGS. 3 to 5.

Referring to FIGS. 3 and 5, in organic light-emitting diodes 200 and 400, a passivation layer 60 may be interposed between the light scattering film 50 and the cathode 40. The passivation layer 60 may prevent the diffusion of materials composing the light scattering film 50 into the organic light-emitting film 30 while forming the light scattering film 50 on the cathode 40. Therefore, the damage of the organic light-emitting layer 30 by the invasion of the materials composing the light scattering film may be prevented. The passivation layer 60 may be formed by a layer material having a high refractive index and excluding a halogen atom. The passivation layer 60 may be a single layer including an organic material, a metal oxide (for example, TiO₂, WO₃, ZnO, ITO, SnO₂, InO₃, ZrO₂) or a metal nitride (for example, MN or SiN). Alternatively, the passivation layer 60 may be a multi layer obtained by stacking a plurality of organic layers and metal oxide layers, or organic layers and metal nitride layers. The organic material may have the refractive index of about 1.7 or above. The organic material may include, for example, 2-TNATA, NPB, 1,1-bis[4-[N,N′-di(p-tolyl)amino]phenyl]cyclohexane (TAPC), 4,4′-dicarbazolyl-1,1′-biphenyl (CBP), TCTA, Alq3, polyquinoline, Alq3, 4,7-diphenyl-1,10-phenanthroline (Bphen), TPBI or N,N′-diphenyl-N,N′-bis-(3-methylphenyl)-1,1′-biphenyl-4,4′-diamine (TPD). The passivation layer 60 may have the thickness of about 10 nm to about 500 nm.

Referring to FIGS. 4 and 5, organic light-emitting diodes 300 and 400 may include metal nanoparticles 52 in the light scattering film 50. In an embodiment, the metal nanoparticles 52 may be formed by using the dielectric material used for forming the light scattering film 50 and a metal material together by means of a co-deposition method. In another embodiment, the metal nanoparticles 52 may be formed after forming the light scattering film 50, by heat treating the light scattering film 50 or by exposing the light scattering film 50 to ultraviolet light. In further another embodiment, the metal nanoparticles 52 may be formed by changing a gas atmosphere to a reducing atmosphere during forming the light scattering film 50.

According to an embodiment, the metal nanoparticles 52 may be composed of the elements of cations composing the dielectric material used for forming the light scattering film 50. For example, the metal nanoparticles 52 may include Ba, Cs, Ca, Pb, Li, Se, Mg, Ag, Te, Sn, Zn, Ti, W, In, Zr or Te. According to another embodiment, the metal nanoparticles 52 formed by the co-deposition method may be composed of the metal materials used in the co-deposition method. The metal nanoparticles 52 may increase the scattering of light in addition to the rough surface of the light scattering film 50, thereby improving the light extracting efficiency of the organic light-emitting diodes 300 and 400.

Hereinafter, the manufacture of an organic light-emitting diode and characteristic simulation of the same will be described in detail with reference to experiment examples performed according to the embodiments of the inventive concept.

Formation of Organic Light-Emitting Diodes.

### Experiment Example

An anode having 100 nm thickness is formed on the substrate. The anode includes Al. An electron transport layer, emission material layer, and hole transport layer are formed on the anode having thicknesses of 60 nm, 5 nm, and 240 nm, respectively to form an organic light-emitting layer. A cathode is formed on the organic light-emitting layer. The cathode includes silver (Ag) and has 20 nm thickness. A passivation layer having a thickness of 60 nm is formed on the cathode. The passivation layer has a refractive index of 1.67. A light scattering film is formed on the passivation layer by depositing AgCl. The light scattering film consists of square pyramid array where each pyramid has a 500 nm width, 500 nm depth, and height 500 nm. The light scattering film has a refractive index of 2.06.

### Comparison Example

An organic light-emitting diode of the comparison example using is manufactured by the same method as the experiment example except for the forming the light scattering film. In the comparison example, forming the light scattering film is omitted.

Table. 1 illustrates a result of simulation of the experiment example and comparison example using FDTD (finite domain time domain) method.

TABLE 1

| | experiment example | comparison example |
|---|---|---|
| summation of | 4.87e⁻⁹ | 1.01e⁻⁸ |
| Electric field intensity | | |

Referring Table. 1, the organic light-emitting diode of the experiment example shows the summation of electric field intensity about two times higher than that of the organic light-emitting diode of comparison example.

Since the organic light-emitting diode of the experiment example includes the light scattering (50), the light extracting efficiency of the organic light-emitting diode of the experiment example may be improved.

The method of manufacturing an organic light-emitting diode according to an embodiment of the inventive concept includes forming a light-scattering film on a cathode. Therefore, the light extracting efficiency of the organic light-emitting diode may be improved. In addition, the light scattering film may be formed by means of a thermal evaporation method, a chemical vapor deposition method or a facing target sputtering method. By applying the above methods, the damage of an emission layer during forming the light scattering film may be minimized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of manufacturing an organic light-emitting diode, the method comprising:
forming an anode on a substrate;
forming an organic light-emitting layer on the anode;
forming a cathode on the organic light-emitting layer; and
forming a light scattering film on the cathode,
the light scattering film being a polycrystalline dielectric material composed of anisotropic crystals, and a surface roughness Ra of a top surface of the light scattering film being greater than or equal to about 50 nm by an anisotropic crystal growth of particles of the dielectric material.

2. The method of manufacturing an organic light-emitting diode of claim 1, wherein the light scattering film is formed by a thermal evaporation method, a chemical vapor deposition method, or a facing target sputtering method, a temperature of the substrate being maintained at 100° C. or less.

3. The method of manufacturing an organic light-emitting diode of claim 1, wherein the dielectric material includes BaCl₂, BaBr₂, BaS, CsCl, CsBr, CsBr₂, PbO, LiCl, LiBr, SeCl₄, MgBr₂, AgCl, AgBr, TeO₂, SnF₄, SnCl₄, SnBr₄, ZnCl₂, TiO₂, WO₃, ZnO, indium tin oxide (ITO), SnO₂, In₂O₃, ZrO₂, AgCl, ZnS or TeO₂.

4. The method of manufacturing an organic light-emitting diode of claim 1, wherein the light scattering film including BaCl₂, BaBr₂, BaS, CsCl, CsBr, CsBr₂, PbO, LiCl, LiBr, SeCl₄, MgBr₂, AgCl, AgBr, TeO₂, SnF₄, SnCl₄, SnBr₄ or ZnCl₂ is formed by a thermal evaporation method.

5. The method of manufacturing an organic light-emitting diode of claim 1, wherein the light scattering film including TiO₂, WO₃, ZnO, indium tin oxide (ITO), SnO₂, In₂O₃ or ZrO₂ is formed by a chemical vapor deposition method.

6. The method of manufacturing an organic light-emitting diode of claim 1, wherein the light scattering film including TiO₂, WO₃, ZnO, indium tin oxide (ITO), SnO₂, In₂O₃, ZrO₂, AgCl, ZnS or TeO₂ is formed by a facing target sputtering method.

7. The method of manufacturing an organic light-emitting diode of claim 1, wherein the light scattering film has a thickness of from about 200 nm to about 2,000 nm.

8. The method of manufacturing an organic light-emitting diode of claim 1, further comprising forming a passivation layer on the cathode prior to forming the light scattering film.

9. The method of manufacturing an organic light-emitting diode of claim 8, wherein the passivation layer includes at least one among an organic material, a metal oxide and a metal nitride.

10. The method of manufacturing an organic light-emitting diode of claim 1, further comprising forming metal nanoparticles in the light scattering film.

11. The method of manufacturing an organic light-emitting diode of claim 10, wherein the metal nanoparticles are formed by a co-deposition method, by performing a heat treatment with the light scattering film, exposing the light scattering film to ultraviolet light, or forming a gas atmosphere into a reducing atmosphere during forming the light scattering film.

12. The method of manufacturing an organic light-emitting diode of claim 10, wherein the metal nanoparticles include Ba, Cs, Ca, Pb, Li, Se, Mg, Ag, Te, Sn, Zn, Ti, W, In, Zr or Te.
